(19) United States
(12) Patent Application Publication
(10) Pub. No.: US 2005/0130420 A1
(43) Pub. Date: Jun. 16, 2005

(54) Cleaning method using ozone DI process

(76) Inventors: Chih Yuan Huang, Hsinchu (TW); Cheng Shun Chen, Hsinchu (TW); Ling-Wuu Yang, Hsinchu (TW)

Correspondence Address: PILLSBURY WINTHROP SHAW PITTMAN LLP, 1650 TYSONS BOULEVARD, MCLEAN, VA, 22102, US

(21) Appl. No.: 10/731,150

(22) Filed: Dec. 10, 2003

(51) Int. Cl. H01L 21/302; H01L 21/461

(52) U.S. Cl. 438/689

(57) ABSTRACT

A semiconductor cleaning method, including providing a semiconductor wafer, forming a first layer of oxide over the semiconductor wafer, forming a floating gate layer over the first layer of oxide, forming a second layer of oxide over the floating gate layer, etching the first layer of oxide, the floating gate layer, and the second layer of oxide to form a gate structure, cleaning the semiconductor wafer including the gate structure using an ozonated de-ionized (DI) water, further cleaning of the ozonated water-cleaned semiconductor wafer using a first cleaning solution, and additional cleaning of the further cleaned semiconductor wafer using a second cleaning solution.

### DESCRIPTION OF THE INVENTION

1. Field of the Invention

This invention is in general related to a method of cleaning silicon wafers and, in particular, to a method of wafer cleaning using ozonated de-ionized (DI) water.

2. Background of the Invention

During the manufacturing process of semiconductor devices, contaminants, such as polymer, photoresist, or insoluble organics, may exist and accumulate on semiconductor wafers, and adversely affect the operations of the semiconductor devices. An example of a semiconductor device including contaminants accumulated during manufacturing process thereof is shown in FIG. 1.

Referring to FIG. 1, a semiconductor device 100 includes a semiconductor substrate 102 and a gate structure (not numbered) of a flash memory cell (not shown). The gate structure includes a layer of tunnel oxide 104, a floating gate 106, and a dielectric layer 108. Floating gate 106 may comprise polysilicon or nitride. Dielectric layer 108 may comprise oxide or a conventional oxide-nitride-oxide multi-layer structure.

During the manufacturing of semiconductor device 100, certain contaminants 110, such as organic residues or metal ions, may remain on the sidewalls of the gate structure of the flash memory cell. Organic residues may be formed during etching, coating, and developing of photoresists. Metal ions may be formed during etching or ion implantation.

In order to obtain a high-performance and high-reliability flash memory, contaminants 110 must be removed, i.e., device 100 has to be cleaned.

A cleaning procedure for silicon wafers developed by RCA Laboratories has become the industry standard, and is generally referred to as RCA cleaning. An RCA cleaning procedure includes three major steps to be performed sequentially:

I. Removal of insoluble organic contaminants with a 5:1:1 H₂O:H₂O₂:NH₄OH solution (standard cleaning solution, referred to as SC1);

II. Removal of a thin silicon dioxide layer where metallic contaminants may accumulate as a result of (I), using a diluted 50:1H₂ O:HF solution; and

III. Removal of ionic and heavy metal atomic contaminants using a solution of 6:1:1H₂O:H₂O₂:HCI (standard cleaning solution, referred to as SC2).

The RCA cleaning procedure has been widely used in semiconductor manufacturing. However, with the advancement of semiconductor technologies and the emergence of a variety of new materials, this cleaning method is no longer adequate for many of the semiconductor manufacturing processes. For example, metals or low-K dielectric materials used in modern semiconductor devices, such as flash memories, may be corroded by the cleaning solutions used in the RCA cleaning procedure.

### SUMMARY OF THE INVENTION

It is therefore an object of the present invention to provide a novel wafer cleaning method that obviates the problems of conventional cleaning method in modern semiconductor device manufactures.

In accordance with the present invention, there is provided a semiconductor cleaning method, including providing a semiconductor wafer, forming a first layer of oxide over the semiconductor wafer, forming a floating gate layer over the first layer of oxide, forming a second layer of oxide over the floating gate layer, etching the first layer of oxide, the floating gate layer, and the second layer of oxide to form a gate structure, cleaning the semiconductor wafer including the gate structure using an ozonated de-ionized (DI) water, further cleaning of the ozonated water-cleaned semiconductor wafer using a first cleaning solution, and additional cleaning of the further cleaned semiconductor wafer using a second cleaning solution.

Also in accordance with the present invention, there is provided a semiconductor cleaning method, including providing a semiconductor wafer, forming a first layer of oxide over the semiconductor wafer, forming a floating gate layer over the first layer of oxide, forming a second layer of oxide over the floating gate layer, forming a layer of nitride over the second layer of oxide, forming a third layer of oxide over the layer of nitride, etching the first layer of oxide, the floating gate layer, the second layer of oxide, the layer of nitride, and the third layer of oxide to form a gate structure, cleaning the semiconductor wafer using an ozonated de-ionized (DI) water, cleaning the semiconductor wafer using a 5:1:1 H₂O:H₂O₂:NH₄OH solution, and cleaning the semiconductor wafer using an ozonated DI water.

Further in accordance with the present invention, there is provided a semiconductor cleaning method, including providing a semiconductor wafer, forming a first layer of oxide over the semiconductor wafer, forming a floating gate layer over the first layer of oxide, forming a second layer of oxide over the floating gate layer, forming a layer of nitride over the second layer of oxide, forming a third layer of oxide over the layer of nitride, etching the first layer of oxide, the floating gate layer, the second layer of oxide, the layer of nitride, and the third layer of oxide to form a gate structure, cleaning the semiconductor wafer using an ozonated de-ionized (DI) water, cleaning the semiconductor wafer using a 6:1:1H₂O:H₂O₂:HCI solution, and cleaning the semiconductor wafer using an ozonated DI water.

Additional objects and advantages of the invention will be set forth in part in the description which follows, and in part will be obvious from the description, or may be learned by practice of the invention. The objects and advantages of the invention will be realized and attained by means of the elements and combinations particularly pointed out in the appended claims.

It is to be understood that both the foregoing general description and the following detailed description are exemplary and explanatory only and are not restrictive of the invention, as claimed.

### BRIEF DESCRIPTION OF THE DRAWINGS

The accompanying drawings, which are incorporated in and constitute a part of this specification, illustrate embodiments of the invention and, together with the description, serve to explain the objects, advantages, and principles of the invention.

In the drawings,

FIG. 1 shows a semiconductor device including contaminants accumulated during manufacturing process thereof;

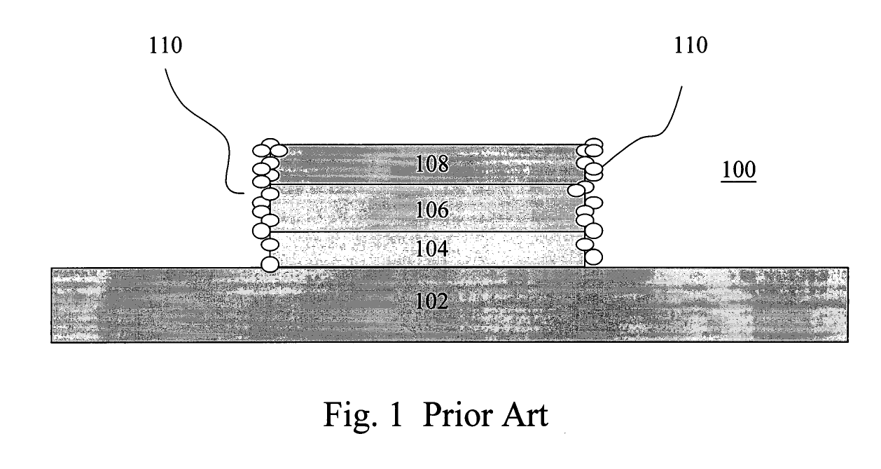

FIG. 2 shows a semiconductor device to be cleaned using a cleaning method consistent with the present invention;

FIG. 3 graphically illustrates measured breakdown charge Q_{BD} of MOS structures manufactured using the cleaning method of the present invention as compared to the standard cleaning methods using SC1 and SC2; and

FIG. 4 graphically illustrates the measured gate coupling ratios (GCR) of the memory device manufactured using the methods of the present invention as compared to the standard cleaning methods using SC1 and SC2.

### DESCRIPTION OF THE EMBODIMENTS

Reference will now be made in detail to the preferred embodiments of the invention, examples of which are illustrated in the accompanying drawings. Wherever possible, the same reference numbers will be used throughout the drawings to refer to the same or like parts.

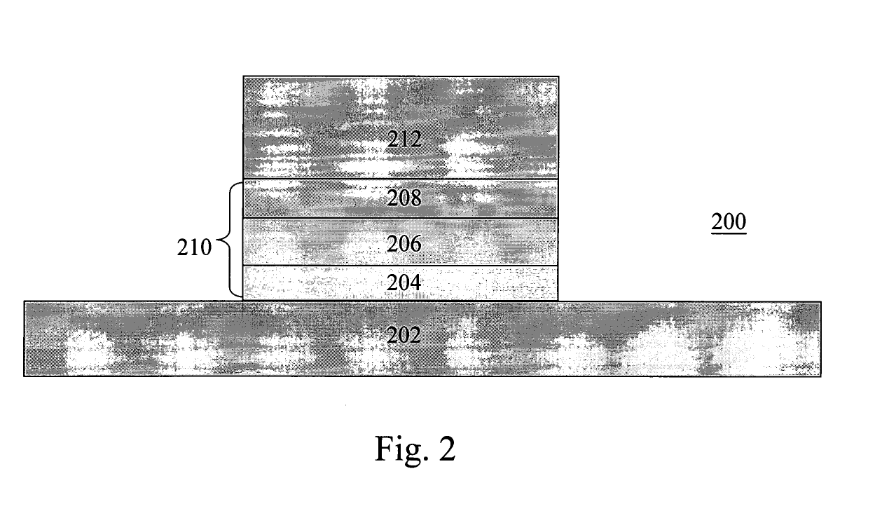

According to the present invention, there is provided a novel method for cleaning semiconductor wafers. FIG. 2 shows a semiconductor device 200 to be cleaned using a cleaning method consistent with the present invention. Referring to FIG. 2, semiconductor device 200 includes a semiconductor substrate 202 with a plurality of devices (not shown) formed thereon. A layer of tunnel oxide 204 is formed over semiconductor substrate 202. A floating gate 206 is formed over tunnel oxide 204. A dielectric layer 208 is formed over floating gate 206. Dielectric layer 208, floating gate 206, and tunnel oxide 204 are then etched to form a plurality of gate structures 210.

Semiconductor substrate 202 may comprise any conventional substrate materials, such as silicon, germanium, or silicon germanium. Floating gate 206 may comprise polysilicon or nitride. Dielectric layer 208 may comprise oxide or an oxide-nitride-oxide (ONO) multi-layer structure. In one aspect, tunnel oxide 204, floating gate 206, and dielectric layer 208 form an ONO structure, wherein floating gate 206 comprises silicon nitride and dielectric layer 208 comprises silicon dioxide.

In one aspect, a step of photolithography may be performed to form certain patterns on the substrate of the wafer, during which photoresist may remain on the substrate. FIG. 2 also shows such a layer of photoresist 212 formed over dielectric layer 208. The cleaning method according to the present invention then follows to remove the photoresist residual:

I. a first rinse with ozonated DI water;

II. a standard cleaning step using a standard cleaning solution; and

III. a second rinse with ozonated DI water,
wherein ozonated DI water is prepared by introducing ozone into DI water. In one aspect, the concentration of ozone in the ozonated DI water is about 10-80 ppm. In another aspect, the concentration of ozone in the ozonated DI water is about 40 ppm.

In a first embodiment of the present invention, the standard cleaning solution is SC1, wherein the proportions of H₂O:H₂O₂:NH₄OH fall in the range of 1:1-5:4-80, i.e., for every part of H₂O, the solution contains 1-5 parts of H₂O₂ and 4-80 parts of NH₄OH. In one aspect, the proportions of H₂O:H₂O₂:NH₄OH are 2.1:3.1:80.

In a second embodiment, the standard cleaning solution is SC2, wherein the proportions of H₂O:H₂O₂: HCI fall in the range of 1:1-5:4-80. In one aspect, the proportions of H₂O:H₂O₂: HCI are 1.3:2.2:80.

According to a third embodiment of the present invention, the cleaning method to remove the photoresist residual may comprise the following steps:

I. a first rinse with ozonated DI water;

II. a cleaning step using an HF/HCI solution; and

III. a second rinse with ozonated DI water.

In one aspect, the proportions of HF:HCI:H₂O in the HF/HCI solution is 1:1.3:400.

Although the photoresist was used as an example in the above description of the present invention, it is to be understood that the cleaning method of the present invention may be used to clean wafers having other contaminants such as polymers, metal ions, or other particles.

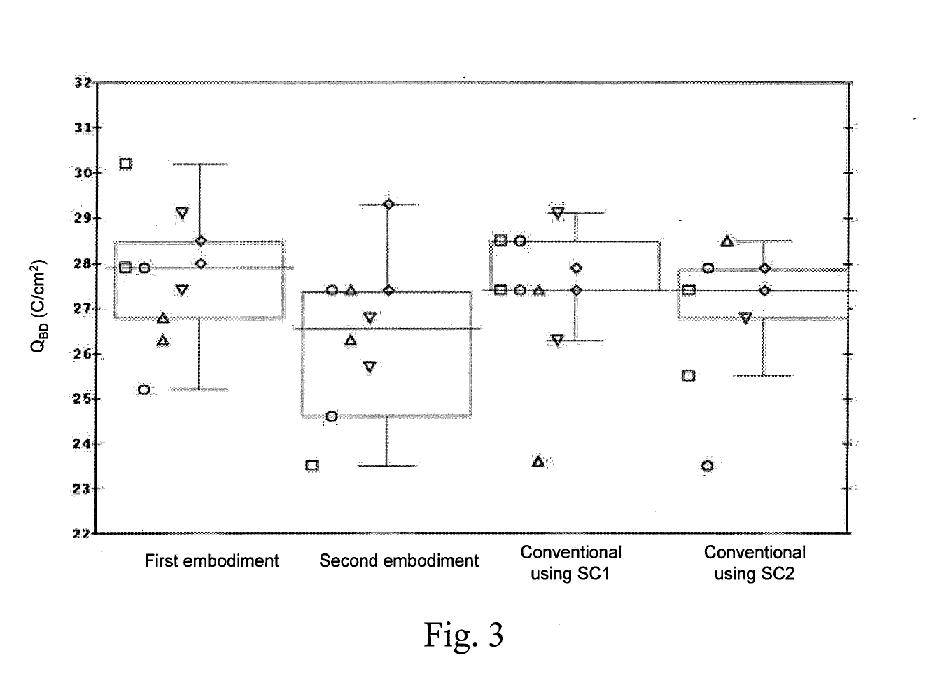

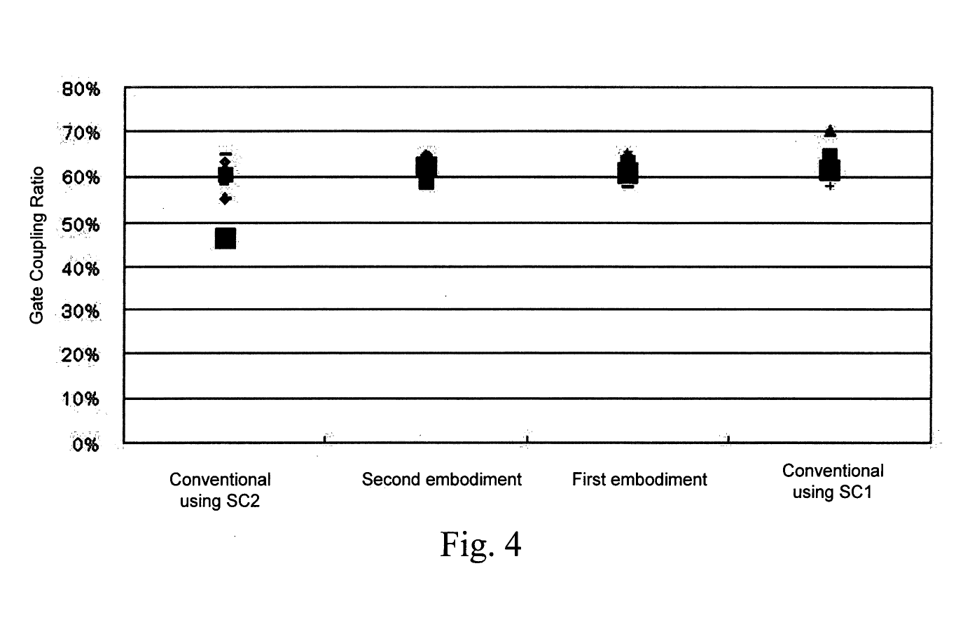

Experiments have been performed to measure the effects of the cleaning methods of the present invention, and the results are illustrated in FIGS. 3 and 4. FIG. 3 graphically illustrates measured breakdown charge Q_{BD} of memory cell structures manufactured using the cleaning method of the present invention as compared to the standard cleaning methods using SC1 and SC2. The horizontal axis indicates four different cleaning procedures and the vertical axis indicates the measured corresponding breakdown charge Q_{BD} for the gate oxide after the cleaning procedures. The four cleaning procedures include the first embodiment of the present invention, wherein the standard cleaning solution SC1 is used, the second embodiment of the present invention, wherein the standard cleaning solution SC2 is used, the conventional standard cleaning method using SC1, and the conventional standard cleaning method using SC2. The breakdown charge Q_{BD} has a unit of Coulomb per cm². Clearly, the methods according to the present invention have comparable performance in the respect of gate breakdown charge Q_{BD}.

FIG. 4 graphically illustrates measured gate coupling ratios (GCR) of the memory device manufactured using the methods of the present invention as compared to the conventional standard cleaning methods using SC1 and SC2. As shown in FIG. 4, the present invention provides for a gate coupling ratio that is comparable to the conventional cleaning method using SC1 but better than the conventional cleaning method using SC2.

Yields were also measured for memory cell devices manufactured using the cleaning method of the present invention as compared to the devices manufactured using conventional cleaning method using the standard cleaning solution SC1. On a wafer having a total of 870 dies, the present invention yielded 754 good dies, while the conventional cleaning method yielded only 682 good dies. The gate structure manufactured using the present invention also showed a very low number of defects—65 (arbitrary unit)—on the sidewalls of the gate structure, as compared to 682 defects (arbitrary unit) using the conventional cleaning method.

According to the above description of the embodiment of the present invention, the cleaning method does not require preparation of all the solutions used in conventional cleaning methods, such as diluted 50:1H₂O:HF solution used in RCA cleaning. As a result, the present invention provides for a lower cost of ownership (CoO) for the manufacturing process, in addition to an improved yield and low defect counts.

It will be apparent to those skilled in the art that various modifications and variations can be made in the disclosed process without departing from the scope or spirit of the invention. Other embodiments of the invention will be apparent to those skilled in the art from consideration of the specification and practice of the invention disclosed herein. It is intended that the specification and examples be considered as exemplary only, with a true scope and spirit of the invention being indicated by the following claims.

1. A semiconductor cleaning method, comprising:
providing a semiconductor wafer;
forming a first layer of oxide over the semiconductor wafer;
forming a floating gate layer over the first layer of oxide;
forming a second layer of oxide over the floating gate layer;
etching the first layer of oxide, the floating gate layer, and the second layer of oxide to form a gate structure;
cleaning the semiconductor wafer including the gate structure using an ozonated de-ionized (DI) water;
further cleaning of the ozonated water-cleaned semiconductor wafer using a first cleaning solution; and
additional cleaning of the further cleaned semiconductor wafer using a second cleaning solution.

2. The method of claim 1, wherein the floating gate comprises polysilicon or nitride.

3. The method of claim 1, wherein the semiconductor wafer has formed therein at least one device.

4. The method of claim 1, wherein the semiconductor wafer has accumulated thereon contaminants accumulated during at least one previous processing step.

5. The method of claim 4, wherein the contaminants comprises polymer.

6. The method of claim 5, wherein the polymer comprises photoresist.

7. The method of claim 1, wherein the first cleaning solution comprises a H₂O:H₂O₂:NH₄OH solution, wherein the proportions of H₂O:H₂O₂:NH₄OH are within the range of 1:1-5:4-80.

8. The method of claim 7, wherein the proportions of H₂O:H₂O₂:NH₄OH are 2.1:3.1:80.

9. The method of claim 1, wherein the first cleaning solution comprises a H₂O:H₂O₂:HCI solution, wherein the proportions of H₂O:H₂O₂:HCI are within the range of 1:1-5:4-80.

10. The method of claim 9, wherein the proportions of H₂O:H₂O₂:HCI are 1.3:2.2:80.

11. The method of claim 1, wherein the first cleaning solution comprises a HF:HCI:H₂O solution, wherein the proportions of HF:HCI:H₂O are 1:1.3:400.

12. The method of claim 1, wherein the concentration of ozone in the ozonated DI water is within the range of 10-80 ppm.

13. The method of claim 12, wherein the concentration of ozone in the ozonated DI water is 40 ppm.

14. The method of claim 1, wherein the second cleaning solution comprises an ozonated DI water.

15. A semiconductor cleaning method, comprising:
providing a semiconductor wafer;
forming a first layer of oxide over the semiconductor wafer;
forming a floating gate layer over the first layer of oxide;
forming a second layer of oxide over the floating gate layer;
forming a layer of nitride over the second layer of oxide;
forming a third layer of oxide over the layer of nitride;
etching the first layer of oxide, the floating gate layer, the second layer of oxide, the layer of nitride, and the third layer of oxide to form a gate structure;
cleaning the semiconductor wafer using an ozonated de-ionized (DI) water;
cleaning the semiconductor wafer using a standard cleaning solution; and
cleaning the semiconductor wafer using an ozonated DI water.

16. The method of claim 15, wherein the floating gate comprises polysilicon or nitride.

17. The method of claim 15, wherein the standard cleaning solution comprises a H₂O:H₂O₂:NH₄OH solution, wherein the proportions of H₂O:H₂O₂:NH₄OH are within the range of 1:1-5:4-80.

18. The method of claim 15, wherein the first cleaning solution comprises a H₂O:H₂O₂:HCI solution, wherein the proportions of H₂O:H₂O₂:HCI are within the range of 1:1-5:4-80.

19. A semiconductor cleaning method, comprising:
providing a semiconductor wafer;
forming a first layer of oxide over the semiconductor wafer;
forming a floating gate layer over the first layer of oxide;
forming a second layer of oxide over the floating gate layer;
forming a layer of nitride over the second layer of oxide;
forming a third layer of oxide over the layer of nitride;
etching the first layer of oxide, the floating gate layer, the second layer of oxide, the layer of nitride, and the third layer of oxide to form a gate structure;
cleaning the semiconductor wafer using an ozonated de-ionized (DI) water;
cleaning the semiconductor wafer using an HF:HCI:H₂O solution; and
cleaning the semiconductor wafer using an ozonated DI water.

20. The method of claim 19, wherein the proportions of HF:HCI:H₂O in the HF:HCI:H₂O solution are 1:1.3:400.
